(19) United States
(12) Patent Application Publication
(10) Pub. No.: US 2016/0118586 A1
(43) Pub. Date: Apr. 28, 2016

(54) METHOD FOR FORMING STACKED STRUCTURE

(71) Applicant: TSINGHUA UNIVERSITY, Beijing (CN)

(72) Inventors: Huaqiang WU, Beijing (CN); Minghao WU, Beijing (CN); Yue BAI, Beijing (CN); He QIAN, Beijing (CN)

(21) Appl. No.: 14/894,502

(22) PCT Filed: May 28, 2014
(86) PCT No.: PCT/CN2014/078690

§ 371 Date: Nov. 28, 2015

(30) Foreign Application Priority Data
May 28, 2013 (CN) 201310204693.1

(51) Int. Cl. H01L 45/00

(52) U.S. Cl. CPC H01L 45/1633; H01L 45/146; H01L 45/1641

(57) ABSTRACT

A method for forming a stacked structure includes steps of: providing a first layer; oxidizing at least a part of the first layer to form a first oxide layer on the first layer; forming a second layer on the first oxide layer; and forming a second oxide layer between the first oxide layer and the second layer by rapid thermal annealing.

### CROSS REFERENCE TO RELATED APPLICATION

This application is a U.S. national phase application of International Application No. PCT/CN2014/078690, filed with the State Intellectual Property Office of P. R. China on May 28, 2014, which claims priority to and benefits of Chinese Patent Application No. 201310204693.1, filed on May 28, 2013, the entire content of which is incorporated herein by reference.

### FIELD

Embodiments of the present invention generally relate to the semiconductor fabrication field, more particularly relate to a method for forming a stacked structure having ultrathin composite oxide layer.

### BACKGROUND

The step of forming an oxide layer, for example, a gate oxide layer or a field oxide layer, is one of the key steps in a semiconductor manufacturing process. With the development of new materials and new structures in the semiconductor field, the application of the oxide layer becomes wider and wider. The method for forming the oxide layer generally includes thermal oxidation and chemical vapor deposition (CVD), ion implanting, and sputtering in oxygen. For example, thermal oxidation of silicon includes dry-oxygen oxidation and wet-oxygen oxidation. As shown in FIG. 1, during the dry-oxygen oxidation, a surface of a silicon sheet is oxidized with dry oxygen at a high temperature, so that a silicon dioxide layer is formed on the surface of the silicon sheet; while during the wet-oxygen oxidation, the surface of the silicon sheet is oxidized with oxygen and water vapor (also referred to as wet oxygen) so as to form a silicon dioxide layer on the surface of the silicon sheet. As described above, the process of forming an oxide layer (such as the silicon dioxide layer) by means of thermal oxidation takes a long time period, and the forming process is hard to control. Further, the formed oxide layer has poor stability and inhomogeneity. CVD has a relatively short forming process, but CVD requires rather high reaction temperatures, and the obtained oxide layers are easy to pollute.

In recent semiconductor manufacturing processes, oxide layers with nanoscale thickness and stacked structures of different materials are commonly used, for example, in resistive random access memory (RRAM). However, these processes may not meet the requirements for the thickness and quality control of the obtained oxide layers.

### SUMMARY

Embodiments of the present invention seek to solve at least one of the problems existing in the prior process engineering, or at least find a valuable way for business application. Accordingly, the objective of the present invention is to provide a method for forming a stacked structure which is easy to operate and control. The composite oxide layer of the stack structure formed by the method according to embodiments of the present invention has a smaller thickness, a compact structure, good stability and excellent uniformity.

According to embodiments of the present invention, a method for forming a stacked structure is provided. The method includes steps of: providing a first layer; oxidizing at least a part of the first layer to form a first oxide layer on the first layer; forming a second layer on the first oxide layer; and forming a second oxide layer between the first oxide layer and the second layer by rapid thermal annealing.

According to the method for forming the stacked structure, as the material of the second layer has an oxygen binding capacity larger than that of the first layer, during the rapid thermal annealing, the second layer is capable of taking oxygen ions from the first layer. Therefore, a part of the second layer can be oxidized by the oxygen ions from the first layer to form the second oxide layer at the contact interface between the first oxide layer and the second layer, even in the absence of additional oxygen. In addition, by controlling a condition (such as temperature, or heating time) of the rapid thermal annealing, the composite oxide layer (including the first oxide layer and the second oxide layer) formed by the method according to embodiments of the present invention not only has a smaller thickness, but also shows the compact structure, good stability and homogeneity.

With the method for forming the stacked structure according to embodiments of the present invention, the ultrathin composite oxide layer including the first oxide layer and the second oxide layer may be formed. In addition, the method is easy to operate, and the thickness of the composite oxide layer may be controlled, for example, by changing related operating conditions.

Additional aspects and advantages of embodiments of present invention will be given in part in the following descriptions, become apparent in part from the following descriptions, or be learned from the practice of the embodiments of the present invention.

### BRIEF DESCRIPTION OF THE DRAWINGS

These and other aspects and advantages of embodiments of the present invention will become apparent and more readily appreciated from the following descriptions made with reference to the accompanying drawings, in which:

FIG. 1 is a schematic diagram showing a process for forming a silicon dioxide layer by a conventional method;

FIG. 2 is a flow chart showing a method for forming a stacked structure according to an embodiment of the present invention;

FIGS. 3a-3d are schematic views illustrating a method for forming a stacked structure according to an embodiment of the present invention;

FIG. 4 shows XPS spectra of a stacked structure according to an embodiment of the present invention;

FIG. 5 shows a TEM image of the stacked structure in FIG. 4;

FIG. 6 shows a TEM image of a stacked structure according to another embodiment of the present invention;

FIG. 7 shows a TEM image of a stacked structure according to a further embodiment of the present invention.

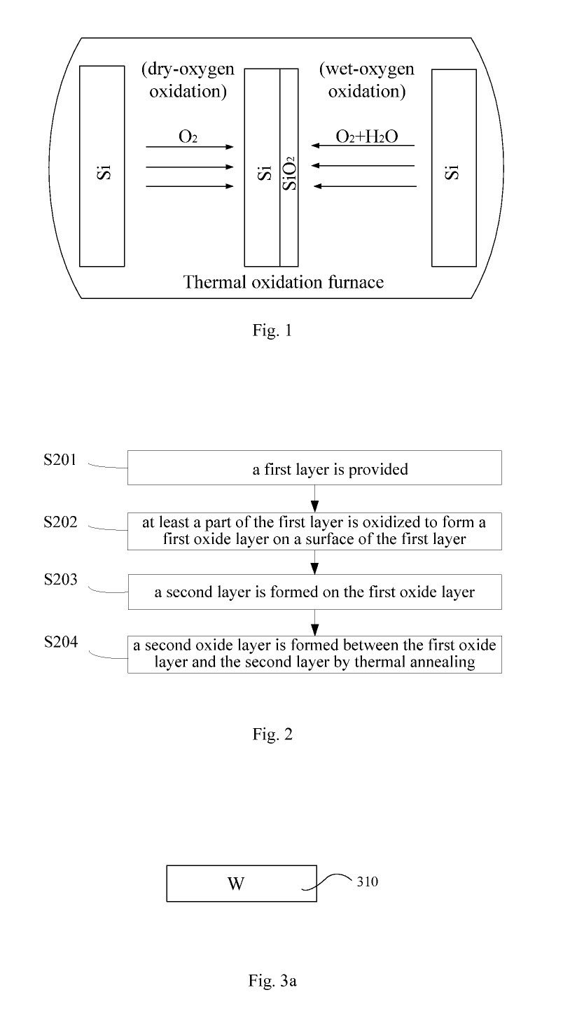

### DETAILED DESCRIPTION

Reference will be made in detail to embodiments of the present invention. The embodiments described herein with reference to drawings are explanatory, illustrative, and used to generally understand the present invention. The embodiments shall not be construed to limit the present invention. The same or similar elements and the elements having same or similar functions are denoted by like reference numerals throughout the descriptions.

Various embodiments and examples are provided in the following description to implement different structures of the present invention. In order to simplify the present invention, certain elements and settings will be described. However, these elements and settings are only examples and are not intended to limit the present invention. In addition, reference numerals may be repeated in different examples in the invention. This repeating is for the purpose of simplification and clarity and does not refer to relations between different embodiments and/or settings. Furthermore, examples of different processes and materials are provided in the present invention. However, it would be appreciated by a person having ordinary skill in the art that other processes and/or materials may be also applied. Moreover, a structure in which a first feature is “on” a second feature may include an embodiment in which the first feature directly contacts the second feature and may include an embodiment in which an additional feature is formed between the first feature and the second feature so that the first feature does not directly contact the second feature.

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items.

In the specification, terms such as “first” and “second” are used herein for purposes of description and are not intended to indicate or imply relative importance or significance.

In the specification, unless specified or limited otherwise, relative terms such as “a plurality of” may refer to two or more than two.

According to embodiments of the present invention, a method for forming a stacked structure is illustrated below with reference to FIG. 2.

As shown in FIG. 2, the method for forming the stacked structure includes the following steps. Step S201, a first layer is provided.

Step S202, at least a part of the first layer is oxidized to form a first oxide layer on the first layer.

Step S203, a second layer is formed on the first oxide layer.

Step S204, a second oxide layer is formed between the first oxide layer and the second layer by thermal annealing.

In some embodiments, the material of the second layer has an oxygen binding capacity larger than that of the first layer. During the rapid thermal annealing, the second layer is capable of taking oxygen ions from the first layer, so that at least a part of the second layer may be oxidized by the oxygen ions, so as to form the second oxide layer between the first oxide layer and the second layer, even in the absence of additional oxygen. In this way, the composite oxide layer including the first oxide layer and the second oxide layer is formed between the first layer and the second layer.

In an embodiment, the first layer is made of tungsten.

In an embodiment, the second layer is made of aluminum.

In some embodiments, the step of oxidizing at least a part of the first layer is performed by dry-oxygen oxidation or wet-oxygen oxidation. The oxidizing of the first layer is not limited, and any method for forming an oxide layer on the first layer may be applied in the present invention, for example, CVD, ion implanting, oxygen sputtering, etc.

In some embodiments, the first oxide layer has a thickness of 30 nm to 80 nm. In one embodiment, the first oxide layer has a thickness of 50 nm.

In some embodiments, the second oxide layer has a thickness of 3 nm to 10 nm. In one embodiment, the second oxide layer has a thickness of 5 nm. A person having ordinary skill in the art will understand that, the thickness of the composite oxide layer (the first oxide layer and the second oxide layer) may be adjusted according to practical requirements, such as a design requirement of the resistive random access memory.

In some embodiments, the rapid thermal annealing is carried out at a temperature of 400° C. to 500° C. for a time period of 50 seconds to 200 seconds. By properly controlling the condition of rapid thermal annealing, the thickness of the composite oxide layer may be controlled, and the composite oxide layer may achieve a stable and uniform structure. In some embodiments, with the increase of the temperature and the annealing time, the thickness and the oxygen content of the second oxide layer may increase accordingly.

In some embodiments, the thermal annealing is carried out in the absence of additional oxygen. Specially, after the oxidation of the first layer to form the first oxide layer, no additional oxygen needs to be supplied to the stacked structure. During the rapid thermal annealing, at least a part of the second layer is oxidized by oxygen ions from the first oxide layer, so as to form the second oxide layer between the first oxide layer and the second layer.

With the method for forming the stacked structure according to embodiments of the present invention, the ultrathin composite oxide layer including the first oxide layer and the second oxide layer may be formed. In addition, the composite oxide layer has a smaller thickness, and a stable and uniform structure, which may be achieved by adjusting the condition of the thermal annealing.

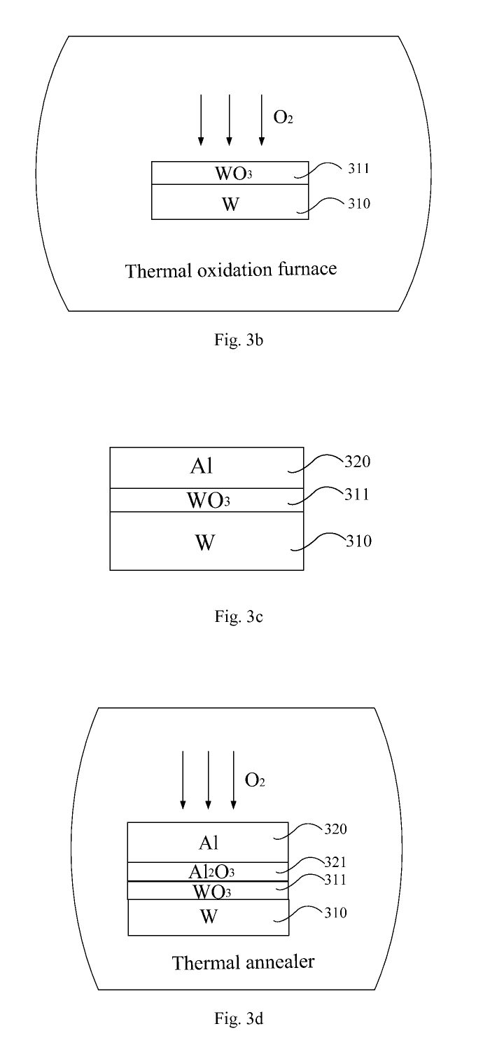

By way of example and without limitations, the method for forming the stacked structure having the composite oxide layer will be described below with reference to FIGS. 3a-3d.

According to an embodiment of the present invention, the first layer and the second layer are made of tungsten and aluminum respectively. As shown in FIG. 3a, firstly a tungsten layer 310 is formed on a surface of a silicon substrate (not shown). For example, the tungsten layer 310 may be formed by means of deposition. Optionally, the tungsten layer 311 may be etched to form a patterned layer. Then, the silicon substrate formed with the tungsten layer 310 is oxidized with oxygen in a thermal oxidation furnace, so that an oxygen-enriched tungsten oxide layer 311 is formed on a surface of the tungsten layer 310, as shown in FIG. 3b. As shown in FIG. 3c, an aluminum layer 320 is formed on a surface of the oxygen-enriched tungsten oxide layer 311 by means of deposition or sputtering. Then, the silicon substrate formed with the aluminum layer 320 is rapidly annealed in a rapid thermal processer at a predetermined condition in the absence of additional oxygen, as shown in FIG. 3d. During the annealing process, as aluminum has an oxygen binding capacity larger than that of tungsten, oxygen atoms may be transferred from the tungsten oxide layer 311 to the aluminum layer 320. Therefore, a surface of the aluminum layer 320 contacted with the tungsten oxide layer 311 may be oxidized by the oxygen atoms to form an aluminum oxide layer 321 between the tungsten oxide layer 311 and the aluminum layer 320.

As described above, the second oxide layer (the aluminum oxide layer) is formed on the surface of the second layer (the aluminum layer) contacted with the first oxide layer, the composite oxide layer may have a smaller thickness, and the method is more simple and effective.

The method for forming the stacked structure having the composite oxide layer will be described with reference to the following examples, which are illustrated herein by way of example and should not be construed as a limit to the present invention.

### Example 1

The present example provides a method for forming a stacked structure E1.

A tungsten layer was formed on a surface of a silicon substrate by sputtering. The tungsten layer was oxidized in a thermal oxidation furnace at a temperature of 450° C. for 100 s, to form an oxygen-enriched tungsten oxide layer on a surface of the tungsten layer. Then, an aluminum electrode was deposited on the tungsten oxide layer. Finally, the silicon substrate formed with the aluminum electrode was annealed in a thermal annealer at a temperature of 400° C. for 30 s. Thus, the stacked structure E1 was obtained.

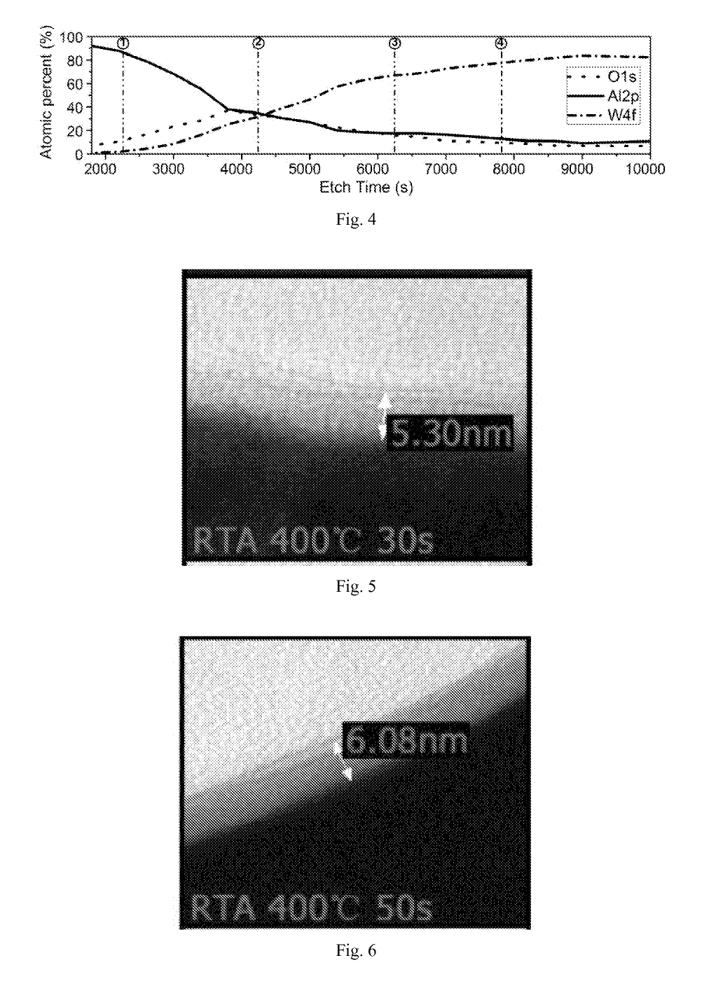

The stacked structure E1 was tested by an X-ray photoelectron spectroscopy (XPS) (ESCALAB 250Xi), and the XPS spectra was shown in FIG. 4.

The stacked structure E1 was tested by a transmission electron microcopy (TEM) (FEI TF20), and the TEM image was shown in FIG. 5.

Referring to FIG. 4, after the annealing, the oxygen content in the oxygen-enriched tungsten oxide layer is significantly reduced, and an aluminum oxide layer is formed between the oxygen-enriched tungsten oxide layer and the aluminum electrode. Therefore, it can be concluded that, during the annealing, the aluminum electrode captures oxygen ions from the oxygen-enriched tungsten oxide layer, so as to oxidize the surface of the aluminum electrode contacted with the oxygen-enriched tungsten oxide layer, so that the aluminum oxide layer is formed between the oxygen-enriched tungsten oxide layer and the aluminum electrode.

As shown in FIG. 5, the tungsten oxide layer has a thickness of 65 nm, and the aluminum oxide layer has a thickness of 5.30 nm.

### Example 2

The present example provides a method for forming a stacked structure E2.

A tungsten layer was formed on a surface of a silicon substrate by sputtering. The tungsten layer was oxidized in a thermal oxidation furnace at a temperature of 450° C. for 100 s, to form an oxygen-enriched tungsten oxide layer on a surface of the tungsten layer. Then, an aluminum electrode was deposited on the tungsten oxide layer. Finally, the silicon substrate formed with the aluminum electrode was annealed in a thermal annealer at a temperature of 400° C. for 50 s. Thus, the stacked structure E2 was obtained.

The stacked structure E2 was tested by a TEM (FEI TF20), and the TEM image was shown in FIG. 6.

As shown in FIG. 6, the tungsten oxide layer has a thickness of 65 nm, and the aluminum oxide layer has a thickness of 6.08 nm.

### Example 3

The present example provides a method for forming a stacked structure E3.

A tungsten layer was formed on a surface of a silicon substrate by sputtering. The tungsten layer was oxidized in a thermal oxidation furnace at a temperature of 450° C. for 100 s, to form an oxygen-enriched tungsten oxide layer on a surface of the tungsten layer. Then, an aluminum electrode was deposited on the tungsten oxide layer. Finally, the silicon substrate formed with the aluminum electrode was annealed in a thermal annealer at a temperature of 450° C. for 50 s. Thus, the stacked structure E3 was obtained.

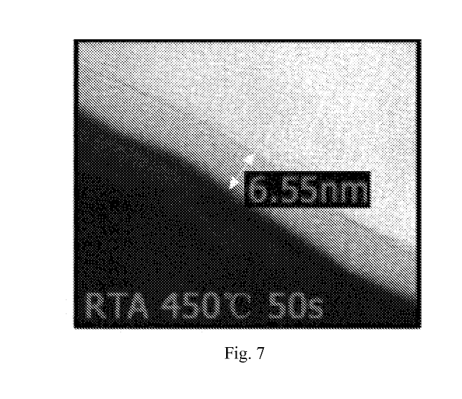

The stacked structure E3 was tested by a TEM (FEI TF20), and the TEM image was shown in FIG. 7.

As shown in FIG. 7, the tungsten oxide layer has a thickness of 65 nm, and the aluminum oxide layer has a thickness of 6.55 nm.

Reference throughout this specification to “an embodiment,” “some embodiments,” “one embodiment”, “another example,” “an example,” “a specific example,” or “some examples,” means that a particular feature, structure, material, or characteristic described in connection with the embodiment or example is included in at least one embodiment or example of the present invention. Thus, the appearances of the phrases such as “in some embodiments,” “in one embodiment”, “in an embodiment”, “in another example,” “in an example,” “in a specific example,” or “in some examples,” in various places throughout this specification are not necessarily referring to the same embodiment or example of the present invention. Furthermore, the particular features, structures, materials, or characteristics may be combined in any suitable manner in one or more embodiments or examples.

Although explanatory embodiments have been shown and described, it would be appreciated by a person having ordinary skill in the art that the above embodiments cannot be construed to limit the present invention, and changes, alternatives, and modifications can be made in the embodiments without departing from spirit, principles and scope of the present invention.

1. A method for forming a stacked structure, comprising steps of:
providing a first layer;
oxidizing at least a part of the first layer to form a first oxide layer on the first layer;
forming a second layer on the first oxide layer; and
forming a second oxide layer between the first oxide layer and the second layer by rapid thermal annealing.

2. The method according to claim 1, wherein the material of the second layer has an oxygen binding capacity larger than that of the first layer.

3. The method according to claim 1, wherein the first layer is made of tungsten.

4. The method according to claim 1, wherein the second layer is made of aluminum.

5. The method according to claim 1, wherein the step of oxidizing at least a part of the first layer is performed by dry-oxygen oxidation or wet-oxygen oxidation.

6. The method according to claim 1, wherein the first oxide layer has a thickness of 30 nm to 80 nm.

7. The method according to claim 1, wherein the rapid thermal annealing is carried out at a temperature of 400° C. to 500° C. for a time period of 50 seconds to 200 seconds.

8. The method according to claim 1, wherein the second oxide layer has a thickness of 3 nm to 10 nm.

9. The method according to claim 1, wherein the rapid thermal annealing is carried out in the absence of additional oxygen.

10. The method according to claim 1, wherein during the rapid thermal annealing, at least a part of the second layer is oxidized by oxygen ions from the first oxide layer, so as to form the second oxide layer between the first oxide layer and the second layer.
